(19) United States
(12) Patent Application Publication
(10) Pub. No.: US 2025/0015036 A1
(43) Pub. Date: Jan. 9, 2025

(54) PREFORMED UNIT OF FAN-OUT CHIP-EMBEDDED PACKAGING PROCESS AND APPLICATION MANUFACTURING METHOD THEREOF

(71) Applicants: LINGSEN PRECISION INDUSTRIES, LTD., TAICHUNG CITY (TW); SOONER POWER SEMICONDUCTOR CO., LTD., HUKOU TOWNSHIP (TW)

(72) Inventors: Yu-Chia CHANG, TAICHUNG CITY (TW); Ming-Feng HSIEH, TAOYUAN CITY (TW)

(21) Appl. No.: 18/447,466

(22) Filed: Aug. 10, 2023

(30) Foreign Application Priority Data
Jul. 6, 2023 (TW) 112125344

(51) Int. Cl. H01L 23/00; H01L 23/495; H01L 23/538; H01L 25/065

(52) U.S. Cl. CPC H01L 24/19; H01L 23/49568; H01L 23/5386; H01L 23/5389; H01L 24/24; H01L 24/96; H01L 25/0655; H01L 2224/19; H01L 2224/24137; H01L 2224/95001; H01L 2224/96; H01L 2924/1011

(57) ABSTRACT

A preformed unit of a fan-out chip-embedded packaging process and an application manufacturing method thereof include: preforming integrated circuit dies into implementation units including chips different in thickness and equipped with electrically conductive pillars of different heights respectively, each chip and the respective electrically conductive pillars being covered by an insulating gel to become the preformed unit; using a carrier to form carrying regions for the preformed units; forming an insulating layer to seal the preformed units; grinding to expose the electrically conductive pillars; arranging wires to connect each electrically conductive pillar with the adjacent chip; forming an insulating layer to cover the wires and making exposing guiding holes, accomplishing a frontside packaging process; removing the carrier to accomplish singulation. It may add another backside packaging process. The present invention is adapted for face-up or face-down packaging process, simplifying the complexity of subsequent chip packaging.

### BACKGROUND OF THE INVENTION

### 1. Field of the Invention

The present invention relates to chip packaging methods and more particularly, to a preformed unit of a fan-out chip-embedded packaging process and an application method thereof, which can simplify the manufacturing process and raise the transmitting efficiency.

### 2. Description of the Related Art

With the more and more advanced semiconductor manufacturing processes, applications such as high-performance computing, 5G communication, Internet of Things, and AR/VR are growing rapidly. The demands for slim appearance, high data transmission rate, low power loss, and low cost have greatly increased the application of advanced packaging processes.

With regard to the fan-out chip advanced packaging process, it is different from the traditional chip packaging. For example, when it has to integrate heterogeneous chips with different thicknesses and different materials for integrated packaging, the different thicknesses of the chips often cause that the face-up process cannot be implemented, but only the face-down process can be implemented. Therefore, the application and implementation thereof are quite limited.

### SUMMARY OF THE INVENTION

It is a primary objective of the present invention to provide a preformed unit of a fan-out chip-embedded packaging process and an application manufacturing method thereof, which can simplify the complexity of packaging various kinds of chips, simplify the packaging process, and lower the packaging cost.

To attain the above primary objective, at first, a preformed unit of a fan-out chip-embedded packaging process of the present invention includes: preforming integrated circuit dies into a plurality of implementation units, the implementation units each including a chip, the chips being different in thickness, and the chips being equipped with electrically conductive pillars of different heights respectively, each of the chips and the respective electrically conductive pillars being wrapped and covered by an insulating gel and diced into a single to become the preformed unit.

Besides, an application manufacturing method of a fan-out chip-embedded packaging process of the present invention includes the steps of: a) preforming integrated circuit dies into a plurality of implementation units, the implementation units including a plurality of chips of different thicknesses, and the chips being equipped with electrically conductive pillars of different heights respectively, each of the chips and the respective electrically conductive pillars being covered by an insulating gel and diced into a single to become a preformed unit; b) then using a carrier to form a plurality of carrying regions for the aforementioned preformed units to be glued therein, and the plurality of preformed units including the same or different chips and different electrically conductive pillar heights; c) forming an insulating layer by gel injection molding to make it completely seal the preformed units; d) performing a grinding process until the electrically conductive pillars of the preformed units are exposed; e) arranging wires to connect each of the electrically conductive pillars of the chips with the adjacent chip, thereby forming a complete wire arrangement; f) forming an insulating layer by gel injection molding again to cover the wires and making exposing guiding holes, thereby accomplishing a frontside packaging process; g) removing the carrier to accomplish a singulation process. Alternatively, it may change into that on the carrier of the step b), high electrically conductive pillars are used to form a plurality of carrying rooms for the preformed units of the step a) to be glued therein; continue the steps c), d) and e) to accomplish arranging electrically conductive wires underneath to add another backside packaging process. As a result, the present invention is adapted for face-up or face-down packaging process according to practical demands, simplifying the complexity of subsequent chip packaging.

In addition, an application manufacturing method of a fan-out chip-embedded packaging process of the present invention includes at least the steps of: a) preforming integrated circuit dies into an implementation unit, the implementation unit including a plurality of chips of different thicknesses, and the aforementioned chips being equipped with electrically conductive pillars of different heights respectively; b) vertically setting a plurality of high electrically conductive pillars on a carrier to form a plurality of carrying regions, the high electrically conductive pillars being higher in height than the aforementioned electrically conductive pillars of the chips; c) covering the chips with a packaging gel to make the chips glued and formed in the carrying regions respectively; d) forming an insulating layer by gel injection molding in a way that space surrounding the high electrically conductive pillars and the chips is filled with insulating gel to be completely sealed so that the high electrically conductive pillars and the chips are completely covered in the insulating layer; e) performing a grinding process; f) arranging wires to connect each of the electrically conductive pillars of the chips with the adjacent high electrically conductive pillar, thereby forming a complete wire arrangement; g) forming an insulating layer by gel injection molding again thereon to cover the wires, and making exposing guiding holes; h) removing the carrier to further perform a chip back grinding process until the back of the earliest exposed chip is exposed to the outside; i) doing the aforementioned steps f) and g) to accomplish frontside and backside optional for subsequent chip packaging process.

Moreover, an application manufacturing method of the fan-out chip-embedded packaging process of the present invention further includes a step j) of continuing to make a heat dissipation layer on the exposed portion of the back of the chip.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 to FIG. 8 are schematic views of the process of a first embodiment of a preformed unit of a fan-out chip-embedded packaging process and an application manufacturing method thereof of the present invention.

FIG. 9 to FIG. 20 are schematic views of the process of a second embodiment of a preformed unit of a fan-out chip-embedded packaging process and an application manufacturing method thereof of the present invention.

### DETAILED DESCRIPTION OF THE INVENTION

First of all, it is to be mentioned that throughout this specification, including the following embodiments and claims, the directional terms are all based on the direction shown in the figures. Besides, same reference numerals used in the following embodiments and the appendix drawings designate same or similar elements or the structural features thereof.

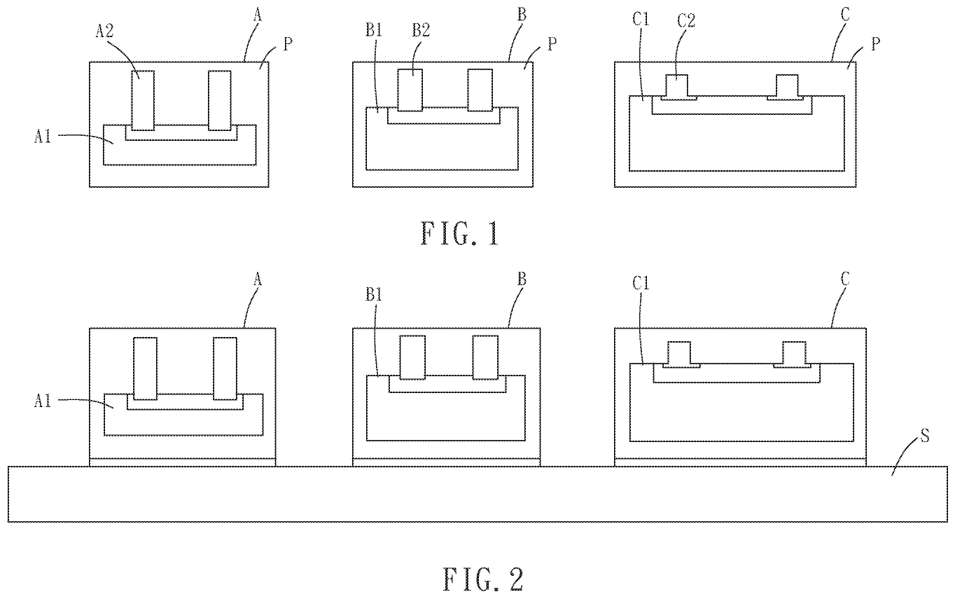

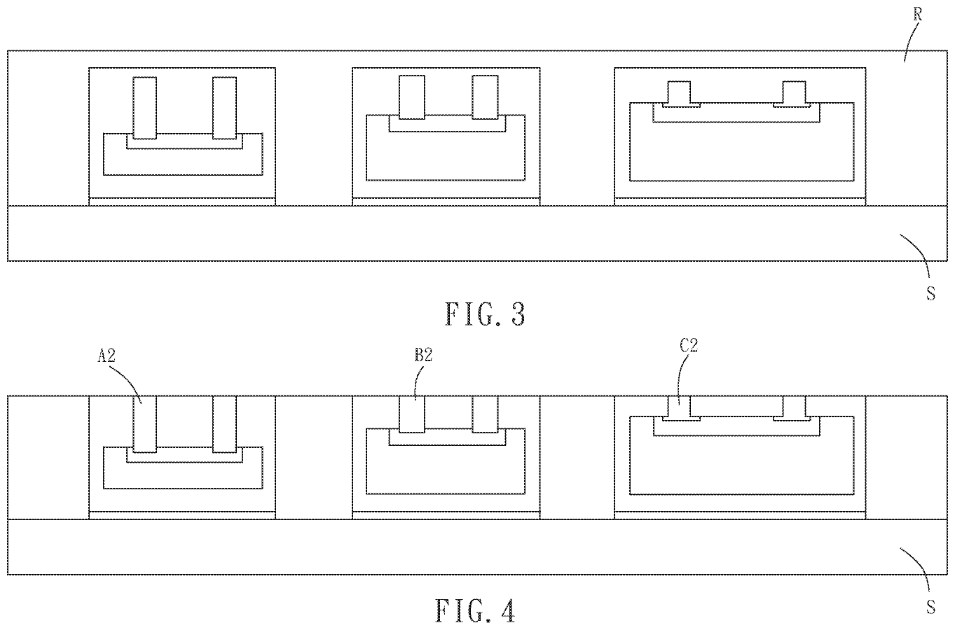

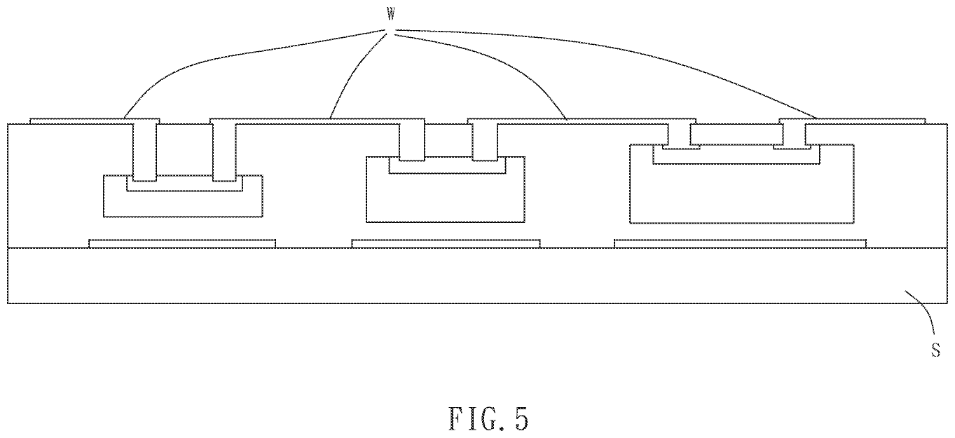

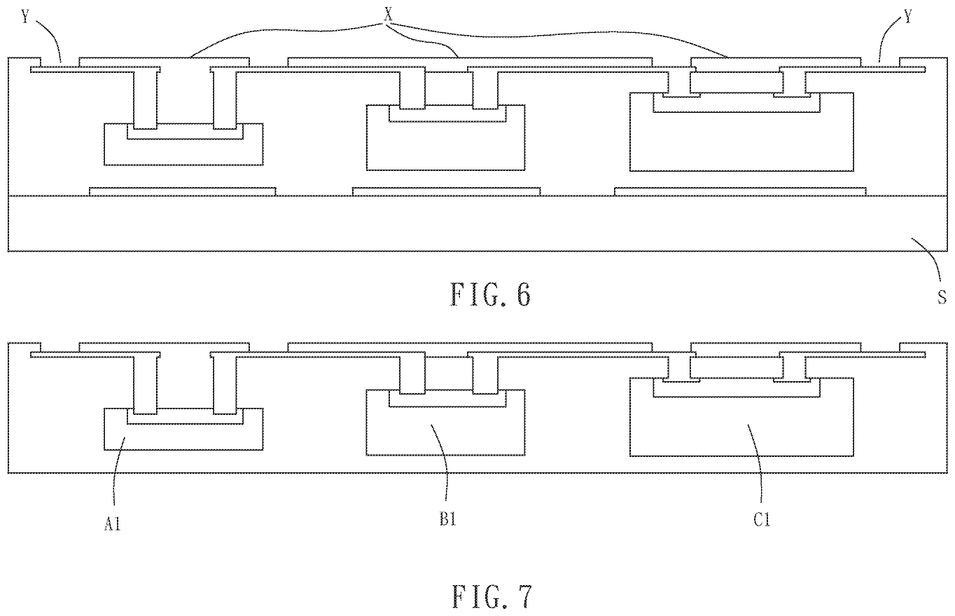

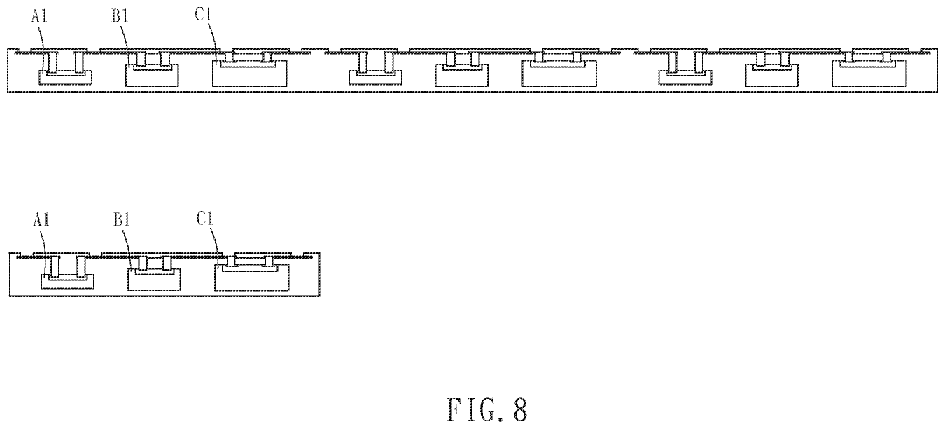

At first, refer to FIG. 1 to FIG. 8 of the first preferred embodiment. In the first preferred embodiment of the present invention, a preformed unit of a fan-out chip-embedded packaging process and an application manufacturing method thereof include the following preformed unit, manufacturing process or called steps.
1) Preform integrated circuit dies into a plurality of implementation units A, B, C. The implementation units include a plurality of chips A1, B1, C1 of different thicknesses, and the chips are equipped with electrically conductive pillars A2, B2, C2 of different heights respectively. Each of the chips A1, B1, C1 and the respective electrically conductive pillars A2, B2, C2 are covered by an insulating gel P to become a preformed unit.
2) Glue the preformed units of the step 1) separately on a carrier S to form a unit module.
3) Mold an insulating gel R on the unit module of the step 2) to form a package forming unit.
4) Then grind the package forming unit of the step 3) until the electrically conductive pillars A2, B2, C2 of the chips are exposed to the outside.
5) Following the step 4), arrange metal connecting wires W to connect the adjacent preformed units.
6) Mold an insulating gel X again on the connecting wires W of the step 5), and form openings Y at appropriate positions.
7) Remove the carrier S of the step 6).
8) Accomplish unit fan-out chip by singulation for subsequent packaging process.

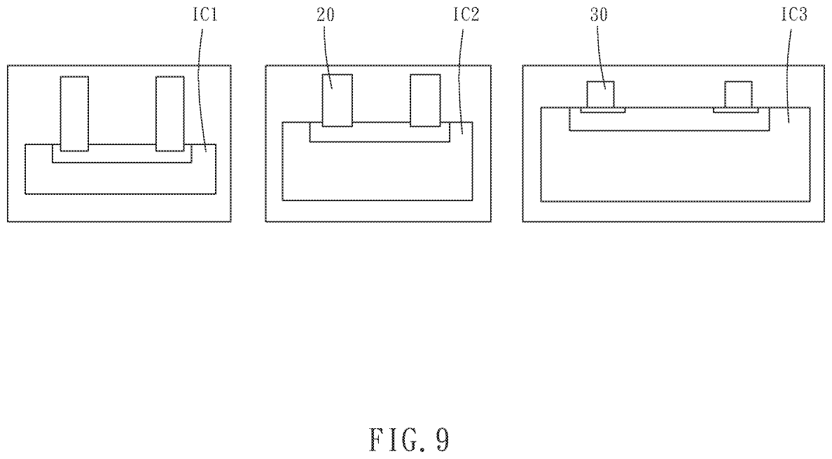

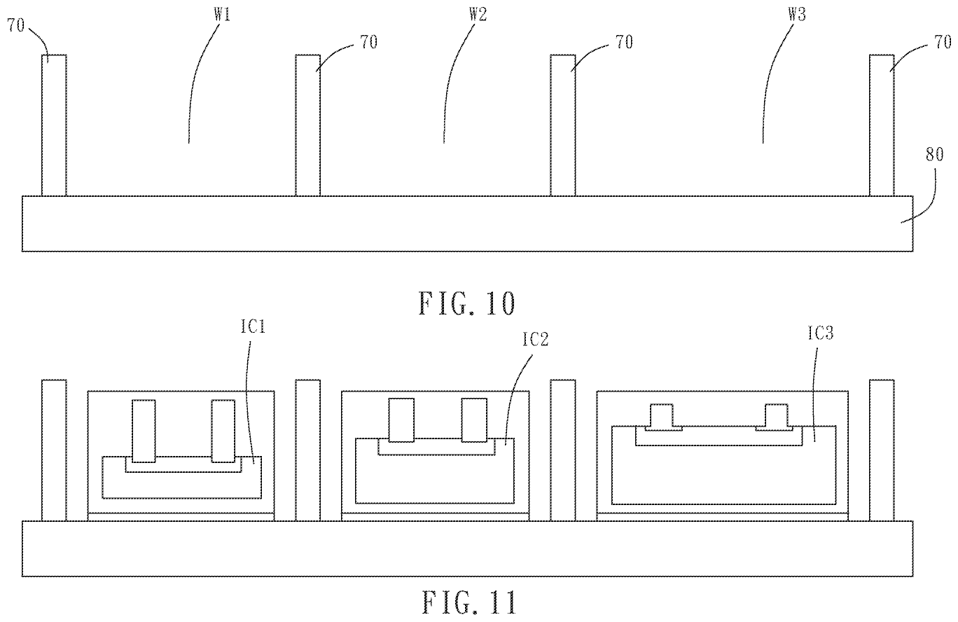

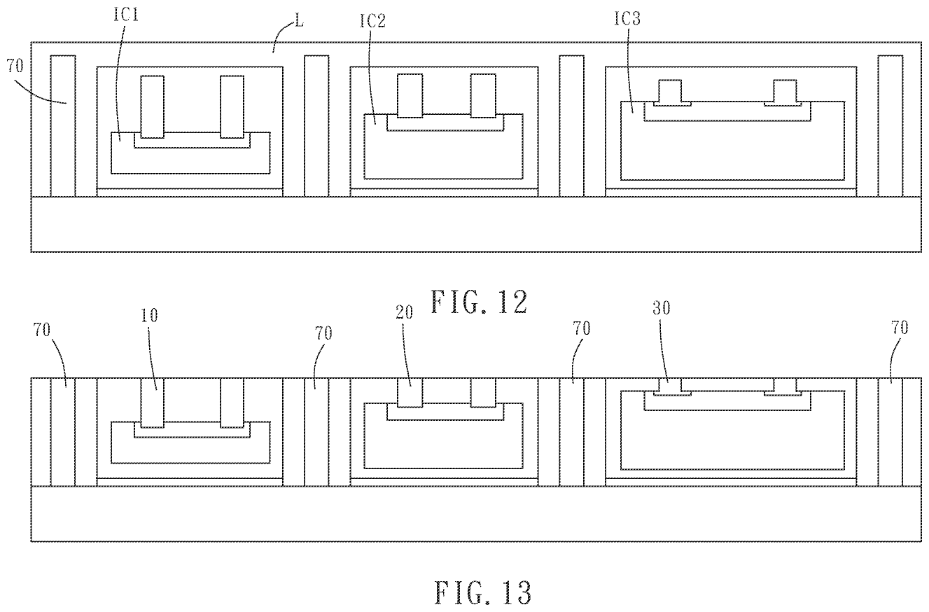

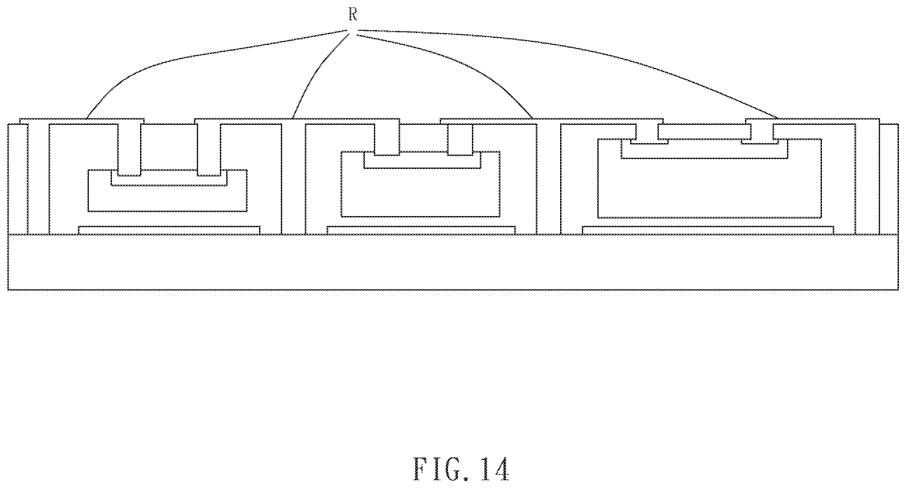

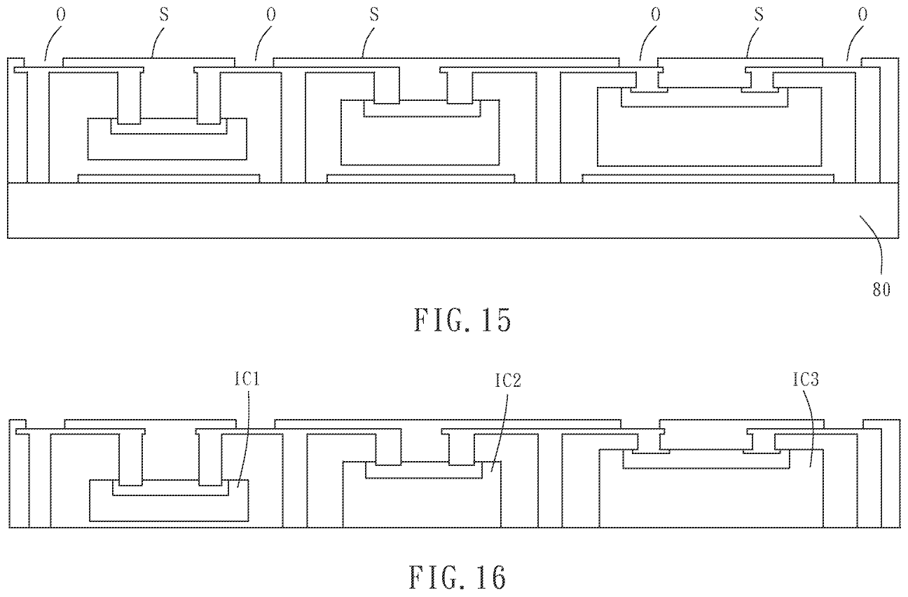

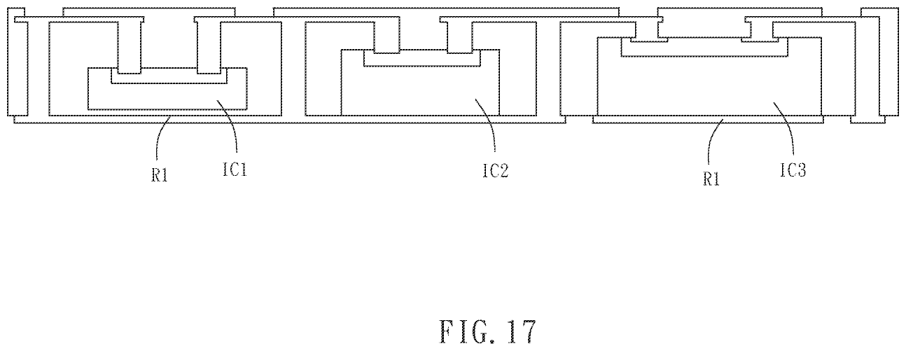

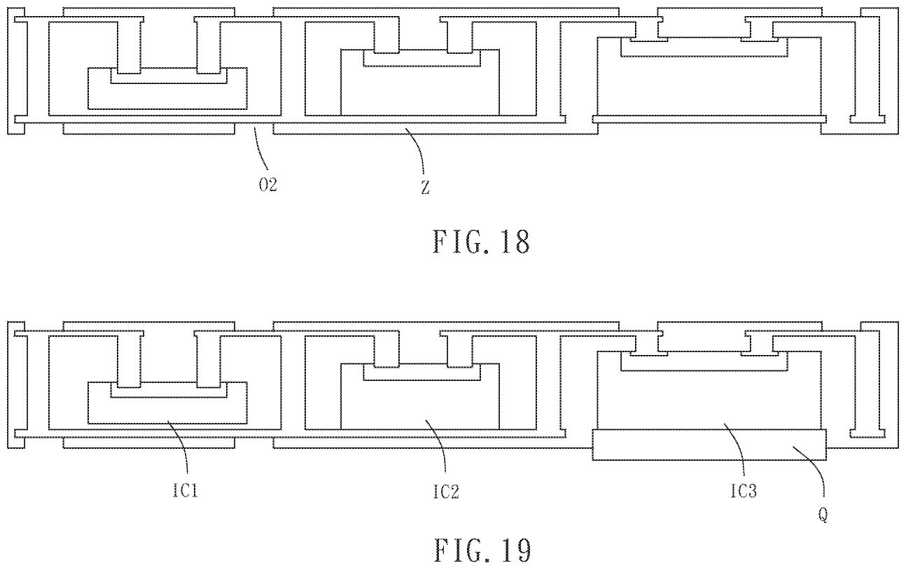

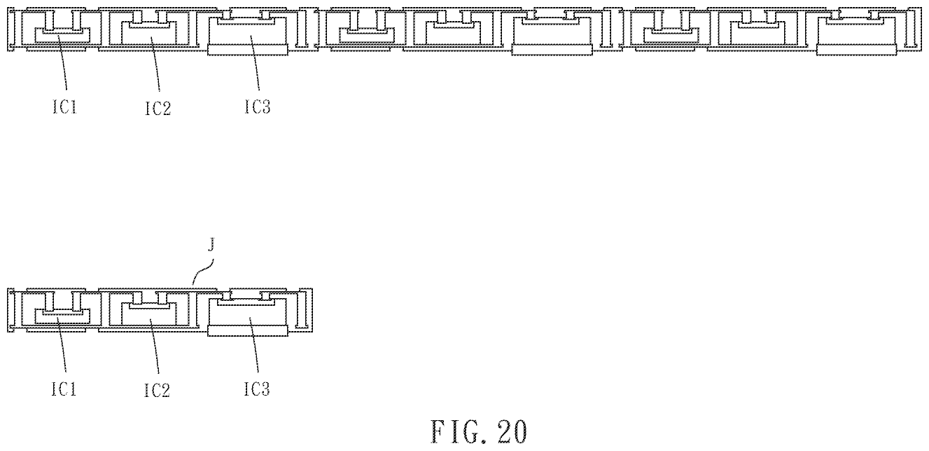

Proceed to refer to FIG. 9 to FIG. 20 of the second preferred embodiment. A fan-out chip packaging process of the second preferred embodiment of the present invention includes the following plurality of steps.
9) Preform integrated circuit dies into an implementation unit. The implementation unit includes three kinds of chips IC1, IC2, IC3 of different thicknesses, and the aforementioned chips are equipped with electrically conductive pillars 10, 20, 30 of different heights respectively.
10) Vertically set a plurality of high electrically conductive pillars 70 on a carrier 80 to form a plurality of carrying regions W1, W2, W3. The high electrically conductive pillars 70 are higher in height than the electrically conductive pillars of different heights of the chips IC1, IC2, IC3 in the preceding paragraph.
11) Glue and preform the various kinds of chips IC1, IC2, IC3 of different thicknesses in the step 9) in the carrying regions W1, W2, W3 of the step 10) respectively. Continue to refer to FIGS. 12, 13 and 14. The second embodiment includes the following three steps.
12) Form an insulating layer L by gel injection molding in a way that space surrounding the high electrically conductive pillars and the chips IC1, IC2, IC3 of the steps 10) and 11) is filled with injected insulating gel to be completely sealed so that the high electrically conductive pillars and the chips IC1, IC2, IC3 of the step 11) are completely covered in the insulating layer.
13) Perform a grinding process by grinding downwardly toward outer edges of the electrically conductive pillars 10, 20, 30 of the chips and the high electrically conductive pillars 70 of the step 12) until the high electrically conductive pillars 70 and the electrically conductive pillars 10, 20, 30 of the chips IC1, IC2, IC3 are exposed to the outside by grinding.
14) Arrange metal wires R to connect each of the electrically conductive pillars of the chips IC1, IC2, IC3 with the adjacent high electrically conductive pillar, thereby forming a complete wire arrangement.
15) Form an insulating layer S by gel injection molding again on 14) to firstly cover the metal wires R, and then perform an etching process at specific positions to make exposing guiding holes O.
16) Remove the carrier 80 to further perform a chip back grinding process until the back of the earliest exposed chip IC3 is exposed to the outside.
17) Arrange metal wires RI again on the backs of the chips IC1, IC2, IC3, forming predetermined metal wire connection.
18) Perform a back insulating layer molding process again to form a protecting layer Z; then perform an etching process to further form exposing guiding holes O2.
19) Continue to make a heat dissipation layer Q on the exposed portion of the back of the chip IC3.
20) Dice the chip module accomplished by the above-described step 9) to step 19) from a wafer, thereby forming a predetermined number of fan-out embedded packaging preformed units J.

As described above, in two embodiments of the preformed unit of the fan-out chip-embedded packaging process and the application manufacturing method thereof provided by the present invention, it primarily preforms and packages at least two chip units, which may be different in thickness, and their respective electrically conductive pillars (copper pillars) of different heights into unit individuals the same in thickness. After that, it may, according to requirements, produce a conduction design on a single side facing upwardly, or further form supporting pillars made of electrically conductive material and controllable in height on the frontside of the chip to be packaged, cover them by an insulating layer higher in height than the electrically conductive pillars and then form exposing guiding holes by etching. Likewise, after the carrier on the backside is removed, the afore-described manufacturing process can be repeated to form another exposing guiding hole adapted for packaging on the backside, and then chip preformed units are formed by dicing for subsequent choice between the frontside and the backside for fan-out chip packaging.

According to the above description, when the preformed unit of the fan-out chip-embedded packaging process and the application manufacturing method thereof of the present invention are often used in heterogeneous chips integrated packaging, the application of the above-described manufacturing process will effectively simplify the complexity of chip packaging, lowering the packaging cost effectively.

What is claimed is:

1. A preformed unit of a fan-out chip-embedded packaging process, which comprises: preforming integrated circuit dies into a plurality of implementation units, the implementation units comprising a plurality of chips of different thicknesses, and the chips being equipped with electrically conductive pillars of different heights respectively, each of the chips and the respective electrically conductive pillars being covered by an insulating gel to become the preformed unit.

2. An application manufacturing method of a fan-out chip-embedded packaging process, the application manufacturing method comprising the steps of: a) preforming integrated circuit dies into a plurality of implementation units, the implementation units comprising a plurality of chips of different thicknesses, and the chips being equipped with electrically conductive pillars of different heights respectively, each of the chips and the respective electrically conductive pillars being covered by an insulating gel to become a preformed unit; b) then using a carrier to form a plurality of carrying regions for the aforementioned preformed units to be glued therein; c) forming an insulating layer by gel injection molding to make it completely seal the preformed units; d) performing a grinding process; e) arranging wires to connect each of the electrically conductive pillars of the chips with the adjacent chip, thereby forming a complete wire arrangement; f) forming an insulating layer by gel injection molding again to cover the wires and making exposing guiding holes, thereby accomplishing a frontside packaging process; g) removing the carrier to accomplish a singulation process.

3. The application manufacturing method as claimed in claim 2, on the carrier of the step b), high electrically conductive pillars being used to form a plurality of carrying rooms for the preformed units of the step a) to be glued therein, continuing the steps c), d) and e) to accomplish arranging electrically conductive wires underneath to add another backside packaging process.

4. An application manufacturing method of a fan-out chip-embedded packaging process, the application manufacturing method comprising the steps of:
a) preforming integrated circuit dies into a plurality of implementation units, the implementation units comprising a plurality of chips of different thicknesses, and the chips being equipped with electrically conductive pillars of different heights respectively, each of the chips and the respective electrically conductive pillars being covered by an insulating gel to become a preformed unit;
b) gluing the preformed units of the step a) separately on a carrier to form a unit module;
c) molding an insulating gel on the unit module of the step b) to form a package forming unit;
d) then continuing to arrange the package forming unit of the step c) with connecting wires to connect the adjacent preformed units according to requirements;
e) molding an insulating gel again on the connecting wires of the step d), and forming openings at appropriate positions for subsequent crystal growth;
f) removing the carrier of the step b) to accomplish unit fan-out chip packaging by singulation.

5. The application manufacturing method as claimed in claim 4, further comprising the steps of:
a) preforming integrated circuit dies into an implementation unit, the implementation unit comprising a plurality of chips of different thicknesses, and the aforementioned chips being equipped with electrically conductive pillars of different heights respectively;
b) vertically setting a plurality of high electrically conductive pillars on a carrier to form a plurality of carrying regions, the high electrically conductive pillars being higher in height than the above-mentioned electrically conductive pillars of the chips;
c) covering the chip with a packaging gel; gluing and preforming the plurality of chips of different thicknesses of the step a) in the carrying regions of the step b) respectively;
d) forming an insulating layer by gel injection molding in a way that space surrounding the high electrically conductive pillars and the chips of the steps b) and c) is filled with injected insulating gel to be completely sealed so that the high electrically conductive pillars and the chips of the step c) are completely covered in the insulating layer;
e) performing a grinding process by grinding downwardly toward outer edges of the electrically conductive pillars of the chips and the high electrically conductive pillars of the step d) until the high electrically conductive pillars and the electrically conductive pillars of the chips are exposed by grinding;
f) arranging wires to connect each of the electrically conductive pillars of the chips with the adjacent high electrically conductive pillar, thereby forming a complete wire arrangement;
g) forming an insulating layer by gel injection molding again thereon to firstly cover the wires, and then performing an etching process at specific positions to make exposing guiding holes;
h) removing the carrier to further perform a chip back grinding process until a back of the earliest exposed chip is exposed to outside;
i) arranging wires again on the backs of the chips, thereby forming a predetermined connecting wire arrangement;
j) performing a back insulating layer molding process again to form a protecting layer; then performing an etching process to further form exposing guiding holes;
k) dicing a chip module accomplished by the above-mentioned step a) to step j) from a wafer, thereby forming a predetermined number of fan-out packaging preformed units.

6. The application manufacturing method as claimed in claim 5, further comprising a step of continuing to make a heat dissipation layer on an exposed portion of the back of the chip between the step j) and the step k).
